(19) United States
(12) Patent Application Publication
(10) Pub. No.: US 2024/0426901 A1
(43) Pub. Date: Dec. 26, 2024

(54) TEMPERATURE ANALYSIS

(71) Applicant: The Regents of the University of Michigan, Ann Arbor, MI (US)

(72) Inventors: Al-Thaddeus Avestruz, Ann Arbor, MI (US); Alireza Ramyar, Ann Arbor, MI (US)

(21) Appl. No.: 18/751,902

(22) Filed: Jun. 24, 2024

Related U.S. Application Data
(60) Provisional application No. 63/522,844, filed on Jun. 23, 2023.

(51) Int. Cl. G01R 31/28

(52) U.S. Cl. CPC G01R 31/2879; G01R 31/2834; G01R 31/2874

(57) ABSTRACT

A temperature monitoring system includes supply circuitry and processing circuitry. The supply circuitry cause variation of an electrical parameter to hold a component-under-test at each of multiple different selected current levels. Curve data for the component-under-test is captured at each of the multiple different selected current levels. The captured curve data is analyzed, via the processing circuitry, to determine temperature information for the component-under-test.

### PRIORITY

This application claims priority to U.S. Provisional Patent Application No. 63/522,844, filed Jun. 23, 2023, and titled TEMPERATURE ANALYSIS, which is incorporated by reference herein in its entirety.

### STATEMENT REGARDING FEDERALLY SPONSORED RESEARCH OR DEVELOPMENT

This invention was made with government support under 1937732 awarded by the National Science Foundation. The government has certain rights in the invention.

### BACKGROUND

### Technical Field

The disclosure relates generally to temperature analysis of electrical components.

### Brief Description of Related Technology

Increasingly complex electronics have given rise to a need for power conversion and other signal processing in various contexts. For example, devices including power supply circuitry may power components at various power levels and/or other input constraints. However, temperature variation may affect device performance. Accordingly, there is increasing demand for systems that efficiently and accurately measure the temperature of components. Improvements to temperature analysis with improve overall device performance and increase demand.

### BRIEF DESCRIPTION OF THE DRAWINGS

FIG. 1 shows an example temperature analysis device.

FIG. 2 shows example monitoring logic.

FIG. 3 shows example multi-stage logic.

FIG. 4 shows an example multiple-stage temperature analysis device.

FIG. 5 shows an example multiplexed temperature analysis device.

FIG. 6 shows an example temperature computation environment.

FIG. 7 shows an example current supply circuit.

FIG. 8 shows an example voltage measurement sensor system.

### DETAILED DESCRIPTION

In various contexts, an electrical system may include various components that may have temperature dependent performance and/or may rely on temperature regulation for operation. In some cases, temperature measurement data may be limited or inaccurate for “in situ” components due to difficulty in accessing the components in an installed device. For example, a transistor within an integrated circuit may be inaccessible for a direct contact temperature measurement. Similarly, a component within a power supply unit, such as a power converter, may have limited contact accessibility. Further, even when direct contact is possible in view of the electronics layout, component casings and other coverings may impede temperature measurement. In some cases, actual component temperature may be estimated from a surface average for the component. Nevertheless, uncertainty due to thermal diffusion through to the surface may introduce error into the measurement.

Additionally or alternatively, the time resolution of various temperature measurements may be limited. Thus, various systems may have limited ability to measure short-timescale temperature characteristics.

The techniques and architectures discussed herein supply a component-under-test with multiple selected current levels. The voltage of the system is varied to hold the component at the selected current levels to obtain voltage curve data. The voltage curve data includes current-level-dependent voltage behavior of the component, which may also be temperature dependent. The voltage curve data at the multiple different current levels may be analyzed to extract temperature data.

In various implementations, various analytic and machine learning systems may be used to extract the temperature data from the voltage curve data. For example, a principal components analysis may be used as discussed in the example implementations. Various other analysis and classification schemes may be used. In various systems, neural networks (such as convolutional neural networks and/or other neural networks) may be used to perform real-time generation of temperature data from captured voltage curve data. In some cases, a training data set with temperature data and voltage curve data (e.g., obtained from principal components analysis, and/or voltage curve capture and contact temperature measurement, and/or via other collection methods) may be used as a ground truth set for training of a neural network.

The techniques and architectures discussed herein allow for temperature information to be extracted from the component itself rather than a sensor in contact with the component. Thus, rather than relying on estimates and/or models regarding thermal diffusion from the component-under-test to the sensor, the techniques and architectures discussed herein allow for actual component temperatures to be measured.

Additionally or alternatively, the techniques and architectures discussed herein allow for calibration of the temperature measurement based on the temperature dependent behavior of the component itself. For example, the component-under-test may be allowed to equilibrate in a temperature bath. Then, calibration may be performed with a known component temperature. In sensor-based temperature measurements, the presence of the sensor and the component within the temperature bath would affect the sensor measurement (e.g., beyond the effects from the component-under-test). Thus, the sensor may be calibrated separately from the component-under-test. Therefore, the relationship between sensor readings and component temperature may be estimated (as discussed above) rather than determined from a calibration process.

Contrary to the conventional wisdom, the techniques and architectures discussed herein determine the temperature for an operative component by supplying multiple selected current levels to the device. Supplying such current levels may be incongruent with desired operation of the component-under-test. While specific single current levels may occur incidentally during component operation, the conventional wisdom holds that supplying multiple currents levels incongruent with desired operation causes undesired operation of the component.

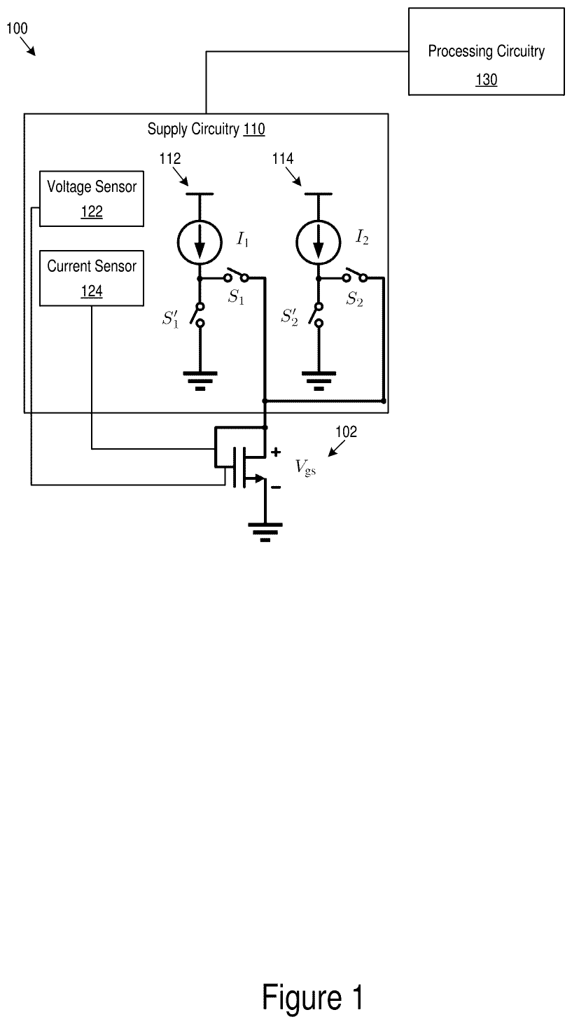

FIG. 1 shows an example temperature analysis device 100. The example temperature analysis device 100 includes supply circuitry 110 and processing circuitry 130. The supply circuitry 110 may be coupled to a component-under-test 102. The supply circuitry may include a voltage sensor 122 and/or a current sensor 124 to sense voltage and/or current inputs/outputs to the component-under-test 102. The supply circuitry 110 may include multiple current supply circuits 112, 114. In the example temperature analysis device 100, two current supply circuits are shown. However, in various implementations additional current supply circuits may be used depending on the number current levels used within the temperature analysis process. For example, in the example multiple-stage temperature analysis device 400, three current supply circuits are used.

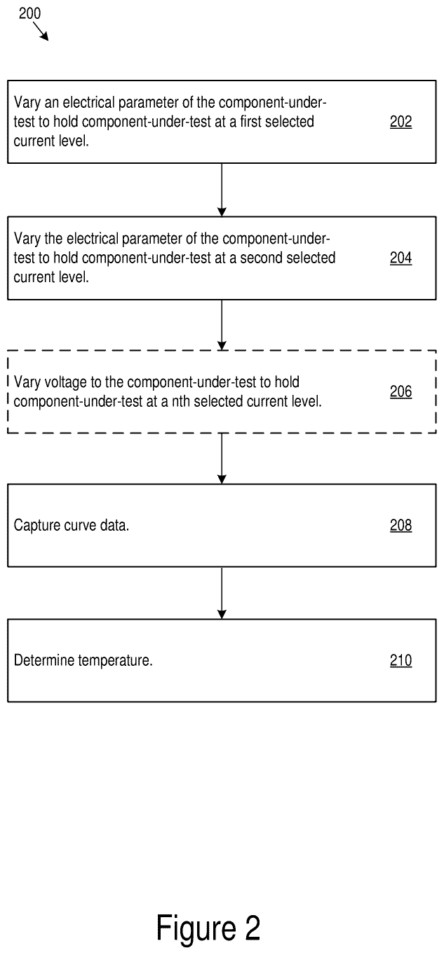

Referring now to FIG. 2, while continuing to refer to FIG. 1, FIG. 2 shows example monitoring logic 200 for operation of the example temperature analysis device 100. The supply circuitry 110 may vary an electrical parameter of the component-under-test 102 to hold the component-under-test 102 at a first selected current level (202). For example, vary the electrical parameter may include supplying a voltage or a current to the component-under-test such that an electrical parameter (e.g., a voltage, current, resistance, or other electrical parameter varies in level. For example varying the electrical parameter may include altering a voltage with time to ensure that the current level driven through the component-under-test 102 remains at the selected level. For example, the supply circuitry 110 may have (or be structured to have) a selected current set point at which to hold the component-under-test 102 and may change the voltage/current output by the supply circuitry 110 to hold the component-under-test 102 at the selected current level. In some implementations, the supply circuitry 110 may include a precision current source that may be configured to output current at a selected level. The voltage/current supplied by the precision current source may be parameter that the precision current source uses to keep the current at the selected level.

The supply circuitry 110 may then vary the electrical parameter of the component-under-test 102 to hold the component-under-test 102 at a second selected current level (204). In some cases, the supply circuitry 110 may hold the component-under-test 102 at third, fourth . . . n^{th} current levels (206). Thus, the supply circuitry 110 may be configured to hold the component-under-test 102 at multiple different selected current levels. Thus, the supply circuitry 110 may be configured to place the component-under-test 102 into different current states for observation/analysis of the component-under-test 102 at the different current states. As discussed below the behavior of the component-under-test 102 in different current states may support analysis for determination of the current temperature of the component-under-test 102.

As an illustrative example of an optional use case, the supply circuitry 110 may be configured to supply a component-under-test including an integrated semiconductor component, such as an electrical component within the active die area of an integrated semiconductor circuit. The supply circuitry 110 may be configured to provide first, second, and third current levels corresponding to below threshold operation (e.g., within a weak inversion region for the semiconductor device), corresponding to at or near threshold operation, and corresponding to above threshold operation (e.g., within a strong inversion region for the semiconductor device). Thus, the supply circuitry may cause the component-under-test 102 to demonstrate behavior in these three operation regimes, e.g., for a semiconductor device. In various implementations, the supply circuitry 110 may be configured to supply the component-under-test 102 such that the different selected current levels correspond to regions where behavior of the relationship, vis-a-vis temperature, between the electrical parameter and the current change. Accordingly, regions where the temperature-dependent relationship may be extracted and mapped by comparing the curve data obtained at each region.

Returning to discussion of the example temperature analysis device 100, the processing circuitry 130 may capture curve data (e.g., via the sensor 112, 114) while the supply circuitry holds the component-under-test 102 at each of the selected current levels (208). The time-varying voltage used to hold the component-under-test 102 at each of the selected current levels may be analyzed to determine a temperature consistent with the behavior collectively at the different levels (210).

The processing circuitry 130 may implement various processing schemes to extract temperature data from the captured curve data. For example, a principal components analysis (PCA) may be used to determine temperature dependent components of the captured curve data to obtain a temperature level (e.g., based on calibration data for the temperature analysis device). For example, PCA may be performed on the temperature dependent curve data (e.g., to reduce the multicollinearity (e.g., the linear dependence on multiple different variables) so that the temperature dependent contribution of the captured curve data can be isolated (at least in part) from other contributions from other variables (e.g., via dimensionality reduction). A regression is performed on the PCA output, to map the temperature dependent contribution of the captured curve data to temperature (e.g., the regression inverts the temperature dependent contribution of the captured curve data, such that this data serves the independent variable in function that has temperature as a dependent variable).

The calibration data may be obtained by placing the example temperature analysis device 100 within a temperature bath. For example, the example temperature analysis device 100 may be placed within a mineral oil bath (or other temperature conductor bath) with a precision temperature controller (such as a feedback controlled heating and/or cooling element). The bath may be set to various temperatures and regression data for electrical parameters (e.g., current, resistance, and/or voltage) may be collected at various temperatures controlled via the bath. Regressions may be generated based on the collected data to support the PCA analysis to be used on collected curve data (e.g., when the temperature is unknown). Thus, two stage operation is possible where calibration is performed and after the initial calibration the example temperature analysis device 100 is used for monitoring of the component-under-test 102.

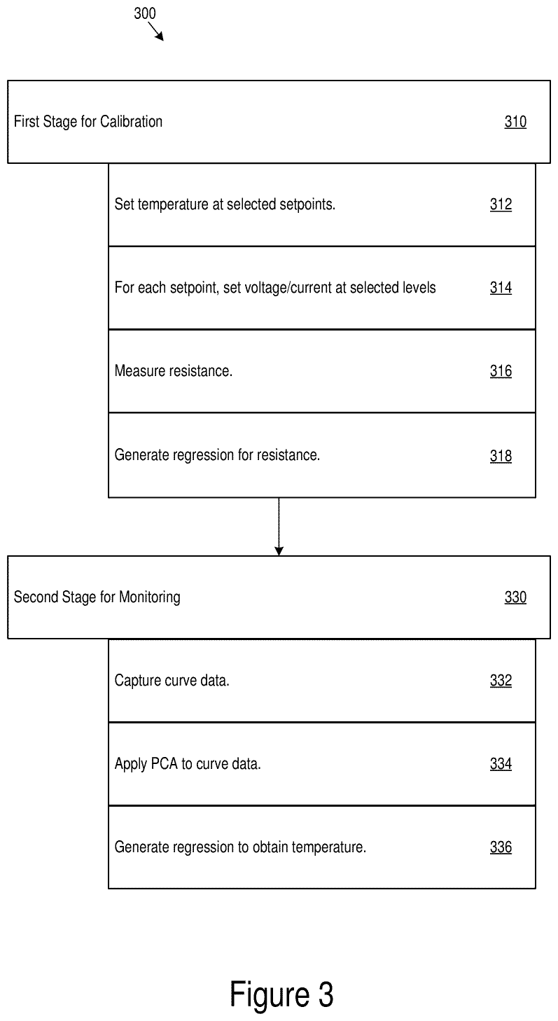

FIG. 3 shows example multi-stage logic 300 for two-stage temperature monitoring. In the first stage for calibration 310, temperature is set at various selected setpoints via a temperature controller in a temperature bath (312). At each of the setpoints, current and/or voltage are set at selected levels (314). The resistance is measured for each of the levels at each of the setpoint (316). A regression of temperature as a function of resistance is generated (318). In the second stage for monitoring 330, curve data for a temperature dependent electrical parameter is captured (332). The temperature dependent electrical parameter may be virtually any electrical parameter of the component-under-test 102 that has temperature dependence. In an illustrative example, the temperature dependent electrical parameter may be voltage at constant current (as discussed above. However, other temperature dependent electrical parameters (such as current at constant voltage, component resistance, and/or other parameters) may be used. The PCA may be applied to the curve data (334). A regression may be generated based on the PCA output (336) to obtain the parameter to temperature mapping for the current state of the component-under-test 102.

In various implementations, PCA and regression analysis provides a robust model for obtaining temperature information from curve data (e.g., at selected constant current levels).

In some implementations, system computational efficiency and computational speed may be enhanced by applying machine learning (ML) and/or artificial intelligence (AI) techniques (such as classification algorithms, image generation, and/or other techniques) to the analysis. For example, an ML and/or AI algorithm may be trained using PCA/regression output as a ground truth result and captured curve data as an input. Using classification schemes and/or generative image outputs, regression and or temperature data outputs may be produced by the trained ML and/or AI algorithm. These outputs may supplant the PCA/regression outputs for increased output speed in monitoring usage (e.g., after initial algorithm training). Additionally or alternatively, such ML and/or AI inputs may be used as an initial start point for the regression generation. In other words, the ML and/or AI inputs are used by e.g., the logic 200 to obtain a head start with in the regression process, e.g., to speed the regression process with increased accuracy in the initial regression guess and/or reduce overall computation expense.

In various implementations, the temperature analysis architectures and techniques discussed herein may be applied within systems with components exposed to an energy dissipative current. For example, the components may be included within an operational device and be placed under load during operation. In some implementations, the energy dissipative load may include a load during an active operational state. In some cases, a component-under-test may operate in different states during different intervals. For example, in a first state during a first interval, the component may be exposed to an energy dissipative current (e.g., to support nominal operation of the component and/or other energy dissipative activity). In the example, in a second state and during a second interval, the component may be exposed to a varying voltage/current to hold the component at selected current levels to support temperature analysis. Thus, the component may be switched between energy dissipative (e.g., active operation) states and one or more temperature monitoring states. The switching may occur at periodic intervals, non-periodic intervals (such as in response to triggering, at pseudorandom intervals, or other non-periodic intervals). The energy dissipative current may cause heating (or other temperature change) within the component. In some cases, the energy dissipative current may be specifically configured for temperature control of the component-under-test, e.g., supply of the energy dissipative current may be implemented as a heater for the component-under-test. Thus, the temperature monitored in the second interval may be due, at least in part, to the energy dissipative current.

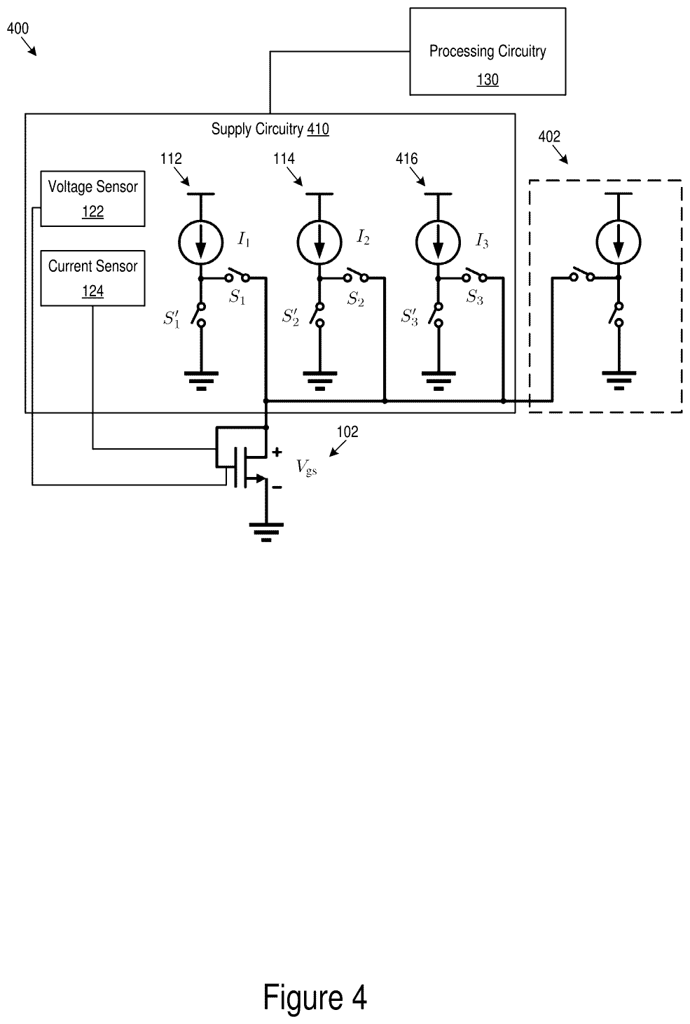

Referring now to FIG. 4, an example multiple-stage temperature analysis device 400 is shown. The example multiple-stage temperature analysis device 400 includes an energy dissipative current supply 402 and a third current supply circuit 416. The energy dissipative current supply 402 may couple to the component-under-test 102 during energy dissipative current intervals to expose the component-under-test 102 under an energy dissipative current. After the first interval, the example multiple-stage temperature analysis device 400 may switch the component-under-test 102 to coupling to the supply circuitry 410 for temperature monitoring during the second interval.

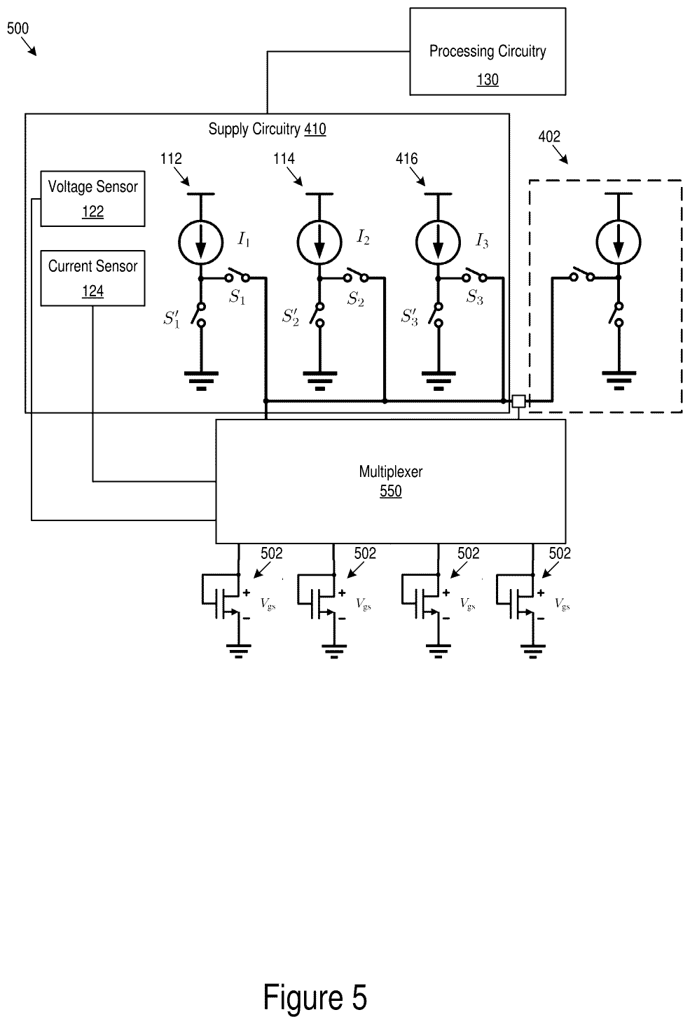

Referring now to FIG. 5, an example multiplexed temperature analysis device 500 is shown. In the example multiplexed temperature analysis device 500, the supply circuitry 110 may be selectively coupled to any one of multiple different components-under-test 502 via a multiplexer 550. The multiplexer 550 may couple the supply circuitry 110 to any of the components-under-test 502. Thus, the supply circuitry 110 in conjunction with processing circuitry 130 may, at different intervals, obtain temperature data from the various ones of the components-under-test. Further, the multiplexer may de-couple a currently selected component-under-test 502 from active operation (e.g., from the energy dissipative current source 402) during its temperature monitoring interval, e.g., to prevent any output generated from temperature probing voltages the currently selected component-under-test 502 from interfering in the nominal operation of the system as a whole).

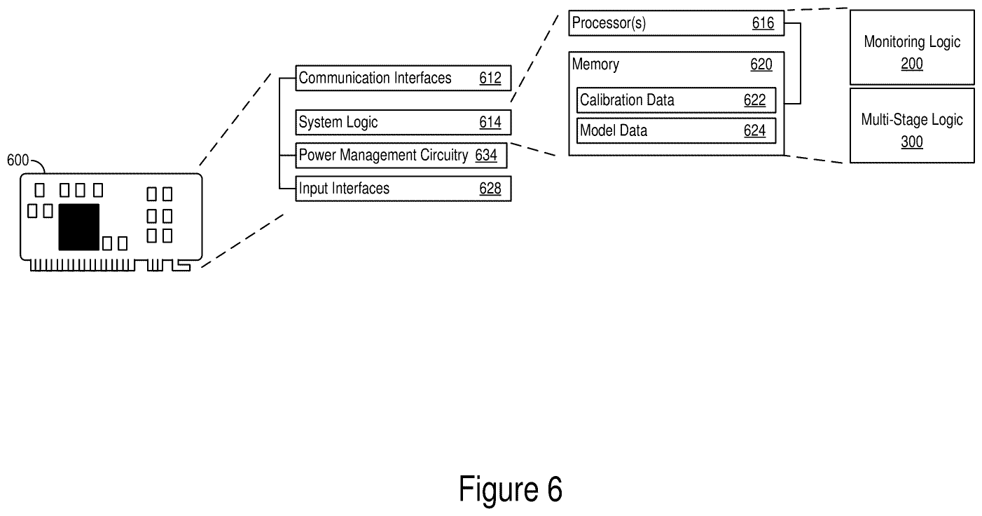

Referring now to FIG. 6, FIG. 6 shows an example temperature computation environment (TCE) 600, which may provide a hardware environment for execution of the logic 200. The TCE 600 may include system logic 614 to support temperature data extraction from electrical parameter curve data. The system logic 614 may include processors 616, memory 620, and/or other circuitry, which may be used to implement the example logic 200.

The memory 620 may be used to store calibration data 622 and/or trained model data 624 that may be used to support PCA-based extraction of temperature data and/or ML/AI assisted extraction schemes.

The memory 620 may further include applications and structures, for example, coded objects, templates, or one or more other data structures to support curve data analysis. The TCE 600 may also include one or more communication interfaces 612, which may support data bus communications, wireless network communications (WIFI, cellular, Bluetooth, and/or other wireless communications), and/or other communication pathways to receive captured electrical parameter data, ML/AI model data, PCA decomposition schemes, calibration data, and/or other operational input. The TCE 600 may include power management circuitry 634 and one or more input interfaces 628.

### Example Implementations

Various illustrative example implementations are included within the drawing sheets for clarity of presentation. However, the various illustrative example implementations should be treated as if included in the specification as indicated below. The illustrative example implementations are illustrative of the general architectures and techniques described above. The various features described with respect to the individual example implementations may be readily integrated with other implementations with or without various other features present in the respective example implementation.

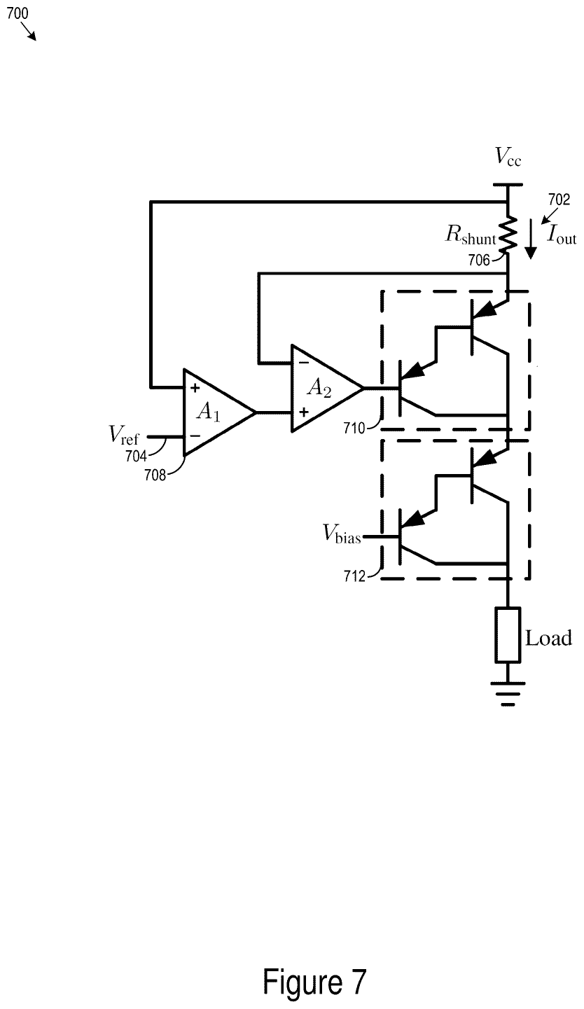

FIG. 7 shows an example current supply circuit 700. The example current supply circuit 700 may be implemented, e.g., as a current supply circuit of the example temperature analysis device 100, example multiple-stage temperature analysis device 400, and/or the example multiplexed temperature analysis device 500. Iₒᵤₜ 702 may be selected via provision of V_{ref} 704 and selection of the resistor 706, Rₛₕᵤₙₜ. In the example current supply circuit 700, level shifting may be provided via an amplifier A1 708. Additionally or alternatively, one or more Darlington structures 710, 712 may be implemented to enhance the output resistance of the current sources. In some cases, increasing output resistance may increase the performance and/or stability of the supply circuitry, e.g., with regard to current provision. In various implementations, the output current may be Iₒᵤₜ=V_{ref}/Rₛₕᵤₙₜ.

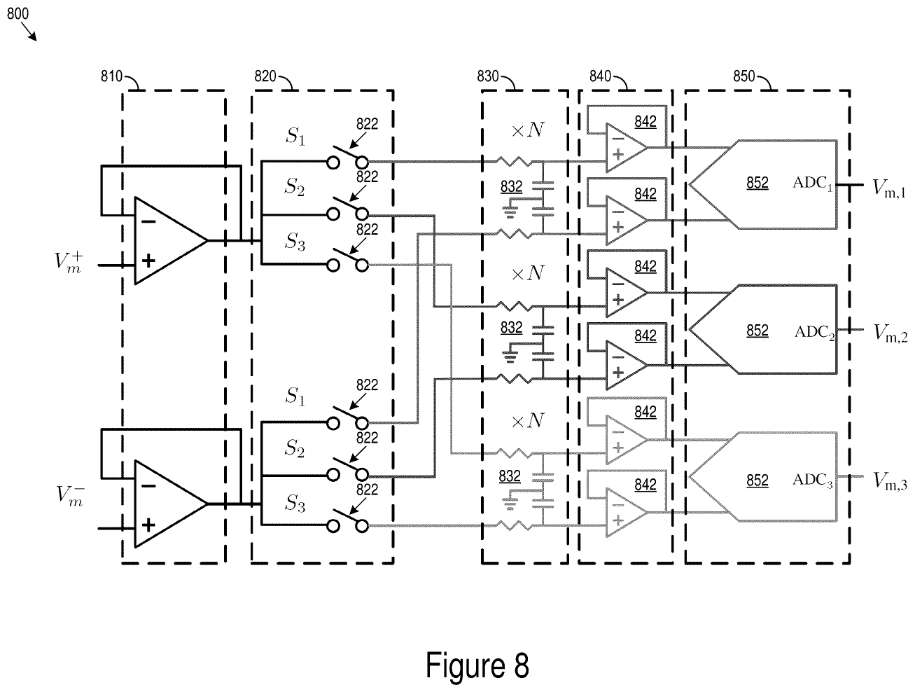

FIG. 8 shows an example voltage measurement sensor system 800. The example voltage measurement sensor system 800 may include multiple stages 810, 820, 830, 840, 850. The example voltage measurement sensor system 800 may be implemented within the devices 100, 400, and/or 500, for example. The first stage 810 may include a buffer stage for differential signals Vₘ₊ and Vₘ₋ from the component-under-test. In the second stage 820, the phase of the measurement is selected via switches 822, e.g., analog switches. A microcontroller may be used to provide control signals for the analog switch. However, various other control circuitry schemes may be used. For example, control for the sensor system may be unified with supply control for supply circuitry and/or capture control for the processing circuitry. The signals may be filtered in the third stage 830 using N cascaded filters 832, e.g., resistor-capacitor (RC) filters. The fourth stage 840 may include voltage followers 842 to drive analog-to-digital converters 852 (ADCs) in the fifth stage 850. In some implementations, and as shown in example voltage measurement sensor system 800, delta-sigma ADCs may be paired with the DC (direct-current) signal outputs from the third stage 830. In some cases, the switches 822 may include switches that are synchronized with the switches used to select the current level, e.g., in the example temperature analysis device 100 and/or the selective switching performed via the multiplexer 550.

The methods, devices, processing, and logic described above may be implemented in many different ways and in many different combinations of hardware and software. For example, all or parts of the implementations may be circuitry that includes an instruction processor, such as a Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be embodied as a signal and/or data stream and/or may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may particularly include a storage medium and instructions stored in or on the medium, and the instructions when executed by the circuitry in a device may cause the device to implement any of the processing described above or illustrated in the drawings.

The implementations may be distributed as circuitry, e.g., hardware, and/or a combination of hardware and software among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

Various implementations have been specifically described. However, many other implementations are also possible.

Table 1 shows various examples.

TABLE 1
Examples

1. A device including:
a component-under-test;
temperature circuitry including:
supply circuitry configured to:
vary an electrical parameter to hold current in the component-under-
test at a selected first current density; and
vary an electrical parameter to hold current in the component-under-
test at a selected second current density different from the first
current density; and
processing circuitry configured to:
capture curve data for the electrical parameter levels used to hold the
circuit at the first and second current densities; and
determine, based at least in part on a curve difference between the
curve data for the first and second current densities, a temperature
of the component-under-test.
2. The device of example 1 or any other example in this table, where
the processing circuitry is configured to determine the temperature
by isolating the curve difference.
3. The device of example 2 or any other example in this table, the
processing circuitry is configured to isolate the curve difference by
performing a principal components analysis on the voltage
curve data.
4. The device of example 2 or any other example in this table, the
processing circuitry is configured to isolate the voltage curve
difference by:
applying a classification algorithm;
performing a machine-learning analysis; and/or
applying a neural network.
5. The device of example 1 or any other example in this table,
where the selected first and second current densities correspond to
different operational current regions of the component-under-test.
6. The device of example 5 or any other example in this table,
where the different operational current regions include:
a below threshold operational region;
an above threshold operational region; and/or
an at or near threshold operational region.
7. The device of example 5 or any other example in this table,
where the different operational current regions include temperature
regions, each temperature region characterized by a different
relationship between current level and the electrical parameter.
8. The device of example 1 or any other example in this table, where
the supply circuitry includes a first current source circuit biased at a
first level to supply the selected first current density and a second
current source circuit biased at a second level to supply the selected
second current density.
9. The device of example 8 or any other example in this table, where:
the first current source is coupled to the component-under-test via a
first shunt resistor and a switch; and
the second current source is coupled to the component-under-test
via a second shunt resistor and the switch, the switch configured to
selectively couple the first and/or second current sources to the
component-under-test.
10. A method including:
supplying current to a component-under-test at multiple different
current densities by varying an electrical parameter to hold the
current at each of the multiple different current densities; and
at each of the multiple different current densities, capturing curve
data while holding the current at the that one of multiple different
current densities; and determining, based at least in part on a curve
difference among the curve data for the multiple different current
densities, a temperature of the component-under-test.
11. The method of example 10 or any other example in this table,
determining the temperature includes isolating the curve difference.
12. The method of example 10 or any other example in this table,
where isolating the curve difference includes performing a principal
components analysis on the curve data.
13. The method of example 10 or any other example in this table,
where determining the temperature of the component-under-test
includes using regression data obtained from a calibration for the
component-under-test, the calibration including holding, via a
temperature bath, the component-under-test at one or more selected
temperature levels and mapping relationship of temperature to one
or more electrical parameters.
14. The method of example 10 or any other example in this table,
where the multiple different current densities correspond to
different operational current regions of the component-under-test.
15. A temperature analysis device including:
a component-under-test;
load current supply circuitry configured to supply the component-
under-test with an energy dissipative current during a first interval;
and temperature circuitry including:
supply circuitry configured to, during a second interval after the
first interval when the component-under-test is not exposed to the
energy dissipative current:
vary an electrical parameter to hold current in the component-
under-test at a selected first current density; and
vary a voltage level to hold current in the component-under-test
at a selected second current density different from the first
current density; and
processing circuitry configured to:
capture curve data for the voltage levels used to hold the circuit
at the first and second current densities; and
determine, based at least in part on a curve difference between
the curve data for the first and second current densities, a
temperature of the component-under-test, the temperature due,
at least in part, to placement under the energy dissipative
current during the first interval.
16. The temperature analysis device of example 15 or any other
example in this table, where:
the first interval includes an interval of operation of the component-
under-test; and
the energy dissipative current includes an operation state current of
the component-under-test; and
the temperature includes an operating state temperature of the
component-under-test.
17. The temperature analysis device of example 16 or any other
example in this table, where:
the second interval includes at least a portion of an idle interval for
the component-under-test.
18. The temperature analysis device of example 16 or any other
example in this table, where:
the component-under-test includes an active logical component
within a die of an integrated circuit.
19. The temperature analysis device of example 15 or any other
example in this table, where the supply circuitry is configured to
alternate between the first and second intervals periodically.
20. The temperature analysis device of example 15 or any other
example in this table, where the supply circuitry coupled to multiple
components-under-test via a multiplexer, the multiple components-
under-test including the component-under-test, the multiplexer
configured to selectively switch the supply circuitry among the
multiple components-under-test.
1P. A device including:
a component-under-test;
temperature circuitry including:
supply circuitry configured to:
vary a voltage level and/or other electrical parameter of the circuit
while supplying current to the component-under-test at a first
current density; and vary a voltage level and/or other electrical
parameter of the circuit while supplying current to the component-
under-test at a second current density different from the first
current density; and
processing circuitry configured to:
capture curve data at the first and second current densities; and
determine, based at least in part on a curve difference between the
first and second current densities, a temperature of the circuit-
under-test.
2P. A method including:
supplying current to a component-under-test at multiple different
current densities; and
at each of the multiple different current densities:
varying a voltage and/or other electrical parameter level;
capturing curve data while varying the voltage and/or other
electrical parameter level; and
determining, based at least in part on a curve difference among the
multiple different current densities, a temperature of the component-
under-test.
3P. A temperature analysis device including:
a component-under-test;
load current supply circuitry configured to place the component-
under-test under an energy dissipative load during a first period
(e.g. to alter the temperature of the component-under-test and/or
cause operation of the component-under-test); and
temperature circuitry including:
supply circuitry configured to, during a second period after the first
period when the component-under-test is not under the energy
dissipative load:
vary a voltage and/or other electrical parameter level of the circuit
while supplying current to the component-under-test at a first
current density; and vary a voltage and/or other electrical parameter
level of the circuit while supplying current to the component-under-
test at a second current density different from the first current
density; and
processing circuitry configured to:
capture curve data at the first and second current densities; and
determine, based at least in part on a curve difference between
the first and second current densities, a temperature of the circuit-
under-test, the temperature due, at least in part, to the energy
dissipative load.
4P. The method or device of any of the other examples in this
table, where the component-under-test includes:
a transistor;
a diode;
a field effect transistor;
a gallium arsenide field effect transistor;
a metal-on-oxide-semiconductor field effect transistor;
a bipolar junction transistor;
an insulated gate bipolar transistor;
a component within a power supply circuit;
a component within an integrated circuit
a component within a processing device;
a component disposed with in a semiconductor die;
a silicon-based semiconductor circuit;
a III-V semiconductor circuit;
a II-VI semiconductor circuit; and/or
other electrical component.
5P. The method or device of any of the other examples in this table,
determining the temperature includes isolating the curve difference.
6P. The method or device of any of the other examples in this table,
where isolating the curve difference includes performing a principal
components analysis on the voltage curve data.
7P. The method or device of any of the other examples in this table,
where isolating the voltage curve difference includes:
applying a classification algorithm;
performing a machine-learning analysis;
applying a neural network; and/or
performing any other computer-based analysis to identify and/or
remove curve components.
8P. The method or device of any of the other examples in this table,
where the multiple current levels correspond to different operational
current regions of the component-under-test, where:
optionally, the different operational current regions include a below
threshold operational region;
optionally, the different operational current regions include an above
threshold operational region; and
optionally, the different operational current regions include an at or
near threshold operational region.
9P. A system including:
circuitry configured supply multiple different current levels to a
component-under-test;
circuitry configured to perform the curve data collection; and/or
circuity (such as processing circuitry configured to execute software)
configured to determine temperature data based on the collected
voltage curve data.
10P. Machine-readable media including instructions configured to
determine temperature data based on collected curve data, where:
optionally, the voltage curve data is collected using any device of or
in accord with the method of any of the other examples;
optionally, the instructions are executable;
optionally, the media is other than a transitory signal;
optionally, the media is non-transitory.
11P. A system including circuitry configured to implement any
feature of the disclosure and/or any combination of features of the
disclosure.
12P. A method including implementing any feature of the disclosure
and/or any combination of features of the disclosure.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device including:
a component-under-test;
temperature circuitry including:
supply circuitry configured to:
vary an electrical parameter to hold current in the component-under-test at a selected first current density; and
vary an electrical parameter to hold current in the component-under-test at a selected second current density different from the first current density; and
processing circuitry configured to:
capture curve data for the electrical parameter levels used to hold the circuit at the first and second current densities; and
determine, based at least in part on a curve difference between the curve data for the first and second current densities, a temperature of the component-under-test.

2. The device of claim 1, where the processing circuitry is configured to determine the temperature by isolating the curve difference.

3. The device of claim 2, the processing circuitry is configured to isolate the curve difference by performing a principal components analysis on the voltage curve data.

4. The device of claim 2, the processing circuitry is configured to isolate the voltage curve difference by:
applying a classification algorithm;
performing a machine-learning analysis; and/or
applying a neural network.

5. The device of claim 1, where the selected first and second current densities correspond to different operational current regions of the component-under-test.

6. The device of claim 5, where the different operational current regions include:
a below threshold operational region;
an above threshold operational region; and/or
an at or near threshold operational region.

7. The device of claim 5, where the different operational current regions include temperature regions, each temperature region characterized by a different relationship between current level and the electrical parameter.

8. The device of claim 1, where the supply circuitry includes a first current source circuit biased at a first level to supply the selected first current density and a second current source circuit biased at a second level to supply the selected second current density.

9. The device of claim 8, where:
the first current source is coupled to the component-under-test via a first shunt resistor and a switch; and
the second current source is coupled to the component-under-test via a second shunt resistor and the switch, the switch configured to selectively couple the first and/or second current sources to the component-under-test.

10. A method including:
supplying current to a component-under-test at multiple different current densities by varying an electrical parameter to hold the current at each of the multiple different current densities; and
at each of the multiple different current densities, capturing curve data while holding the current at the that one of multiple different current densities; and
determining, based at least in part on a curve difference among the curve data for the multiple different current densities, a temperature of the component-under-test.

11. The method of claim 10, determining the temperature includes isolating the curve difference.

12. The method of claim 10, where isolating the curve difference includes performing a principal components analysis on the curve data.

13. The method of claim 10, where determining the temperature of the component-under-test includes using regression data obtained from a calibration for the component-under-test, the calibration including holding, via a temperature bath, the component-under-test at one or more selected temperature levels and mapping relationship of temperature to one or more electrical parameters.

14. The method of claim 10, where the multiple different current densities correspond to different operational current regions of the component-under-test.

15. A temperature analysis device including:
a component-under-test;
load current supply circuitry configured to supply the component-under-test with an energy dissipative current during a first interval; and
temperature circuitry including:
supply circuitry configured to, during a second interval after the first interval when the component-under-test is not exposed to the energy dissipative current:
vary an electrical parameter to hold current in the component-under-test at a selected first current density; and
vary a voltage level to hold current in the component-under-test at a selected second current density different from the first current density; and
processing circuitry configured to:
capture curve data for the voltage levels used to hold the circuit at the first and second current densities; and
determine, based at least in part on a curve difference between the curve data for the first and second current densities, a temperature of the component-under-test, the temperature due, at least in part, to placement under the energy dissipative current during the first interval.

16. The temperature analysis device of claim 15, where:
the first interval includes an interval of operation of the component-under-test; and
the energy dissipative current includes an operation state current of the component-under-test; and
the temperature includes an operating state temperature of the component-under-test.

17. The temperature analysis device of claim 16, where:
the second interval includes at least a portion of an idle interval for the component-under-test.

18. The temperature analysis device of claim 16, where:
the component-under-test includes an active logical component within a die of an integrated circuit.

19. The temperature analysis device of claim 15, where the supply circuitry is configured to alternate between the first and second intervals periodically.

20. The temperature analysis device of claim 15, where the supply circuitry coupled to multiple components-under-test via a multiplexer, the multiple components-under-test including the component-under-test, the multiplexer configured to selectively switch the supply circuitry among the multiple components-under-test.
